(19) United States
(12) Patent Application Publication
(10) Pub. No.: US 2026/0261099 A1
(43) Pub. Date: Sep. 3, 2026

(54) OPTICAL ELEMENT ASSEMBLY, OPTICAL ASSEMBLY MANUFACTURING METHOD, OPTICAL MODULE, OPTICAL ENGINE, AND XR GLASSES

(71) Applicant: TDK Corporation, Tokyo (JP)

(72) Inventors: Takashi HONDA, Tokyo (JP); Ryohei FUKUZAKI, Tokyo (JP); Tsuyoshi KOMAKI, Tokyo (JP)

(73) Assignee: TDK Corporation, Tokyo (JP)

(21) Appl. No.: 19/543,199

(22) Filed: Feb. 18, 2026

(30) Foreign Application Priority Data
Feb. 28, 2025 (JP) 2025-032161

(51) Int. Cl. H01S 5/40; G02B 6/43; G02B 27/01

(52) U.S. Cl. CPC H01S 5/4012; G02B 6/43; G02B 27/0172; H01S 5/4093; G02B 2027/0178

(57) ABSTRACT

An optical element assembly includes a plurality of laser diode assemblies and an optical waveguide substrate having a main surface on which an optical waveguide layer having an optical waveguide for guiding laser light output from the plurality of laser diode assemblies is provided. Each of the laser diode assemblies includes a base plate and a laser diode formed on the base plate. At least one of the plurality of laser diode assemblies is provided at a spacing from an adjacent laser diode assembly so that a mounting pitch satisfies formula (1), P≥W+0.9T . . . (1). (P denotes a mounting pitch, W denotes a width of the base plate, and T denotes a thickness of the base plate).

### BACKGROUND OF THE INVENTION

### Field of the Invention

The present invention relates to an optical element assembly, an optical assembly manufacturing method, an optical module, an optical engine, and XR glasses.

### Description of Related Art

Optical element assemblies for extended reality (XR) glasses having a plurality of laser light sources, such as augmented reality (AR) glasses and virtual reality (VR) glasses, are expected to be compact wearable devices. The key to the widespread adoption of wearable devices such as AR glasses and VR glasses is miniaturization so that each function fits into the size of a regular pair of glasses.

A typical optical element assembly is one in which light is guided from a laser diode to an optical element through an optical fiber or the like and alignment and bonding of the fiber are performed using a resin or the like (e.g., Patent Documents 1 and 2). In an optical element assembly having such a structure in which a laser diode is directly attached to an optical element having a plurality of waveguides, the laser diode is bonded onto a subcarrier, and then one surface of the subcarrier is used as a bonding surface to bond the laser diode with an adhesive according to a technique.

Moreover, an element in which a laser diode is directly aligned with a waveguide and bonded to the waveguide for optical coupling is shown with respect to an optical element having a plurality of optical waveguides and configured to perform some type of optical or photoelectric conversion. For such elements, a structure in which bonding is performed by eutectic bonding such as AuSn bonding has been proposed (e.g., Patent Document 3).

### Patent Documents

[Patent Document 1] PCT International Publication No. WO/2019/239839
[Patent Document 2] Japanese Unexamined Patent Application, First Publication No. 2024-58375
[Patent Document 3] Japanese Unexamined Patent Application, First Publication No. 2024-147277

### SUMMARY OF THE INVENTION

In the structures described in Patent Documents 1 and 2, in the case of adhesive bonding, it is necessary to provide a gap between the laser diode assemblies using a coating method, bonding jig, or the like in a bonding process, and a waveguide pitch is decided thereby.

Even when eutectic bonding is used, a reflow method is crucial. Specifically, during reflow, care must be taken to ensure that laser diode units, which are not being bonded, are not affected by the heat of the laser diode that is being bonded and is located nearby.

Moreover, when a plurality of laser fibers are bonded, a pitch of a waveguide is limited by a process or a part, such as a size of a coupler of a bonding part, an arrangement of jigs, or an adhesive application method.

The present invention has been made in view of the above circumstances and an objective of the present invention is to provide an optical element assembly, a method for manufacturing the optical element assembly, an optical module, an optical engine, and XR glasses in which laser diode assemblies are mounted with high accuracy so that no thermal influence occurs on other laser diode assemblies when a base plate on which the laser diode is formed is bonded to an optical waveguide substrate, and which offers a high degree of freedom in selecting a mounting position according to a shape of the laser diode assembly.

To solve the above-described problems, the present invention provides the following means.
[1] According to an aspect of the present invention, there is provided an optical element assembly including:
a plurality of laser diode assemblies; and
an optical waveguide substrate having a main surface on which an optical waveguide layer having an optical waveguide for guiding laser light output from the plurality of laser diode assemblies is provided,
wherein each of the laser diode assemblies includes a base plate and a laser diode formed on the base plate, and
wherein at least one of the plurality of laser diode assemblies is provided at a spacing from an adjacent laser diode assembly so that a mounting pitch satisfies formula (1).

$$P \geq W + 0.9 T \qquad ( 1 )$$

(P denotes a mounting pitch, W denotes a width of the base plate, and T denotes a thickness of the base plate)
[2] In the optical element assembly according to the above-described [1], the plurality of laser diode assemblies may be provided at unequal pitches.
[3] In the optical element assembly according to the above-described [1] and [2], the plurality of laser diode assemblies may be provided at spacings so that adjacent laser diode assemblies have the mounting pitch satisfying formula (1).
[4] In the optical element assembly according to the above-described [1] to [3], the plurality of laser diode assemblies may be provided so that spacings between the adjacent laser diode assemblies are equal.
[5] In the optical element assembly according to the above-described [1] to [4], the plurality of laser diode assemblies may be bonded to the optical waveguide substrate via a plurality of metallic films, respectively.
[6] In the optical element assembly according to the above-described [1] to [5], the plurality of metallic films may include Sn and Au.
[7] In the optical element assembly according to the above-described [1] to [6], the plurality of laser diode assemblies may be formed so that a mounting pitch satisfies formula (2).

$$P \leq Wo - nW \qquad ( 2 )$$

(Wo denotes a width of the optical element assembly and n denotes the number of laser diode assemblies included in the optical element assembly)
[8] In the optical element assembly according to the above-described [1] to [7],
the plurality of laser diode assemblies may include at least two first laser diode assemblies adjacent to each other and bonded to the optical waveguide substrate via a plurality of metallic films and at least one second laser diode assembly adhered to the optical waveguide substrate via an adhesive layer,
the adjacent first laser diode assemblies among the plurality of laser diode assemblies may be provided at spacings P so that the mounting pitch satisfies formula (1), and
a spacing between the second laser diode assembly and an adjacent laser diode assembly may be less than the spacing P.
[9] In the optical element assembly according to the above-described [1] to [8], the plurality of metallic films may include a eutectic film of Sn and Au or a eutectic film of Sn and Pt.
[10] The optical element assembly according to the above-described [1] to [9] may further include a base in which the base plate and the optical waveguide substrate are bonded via an adhesive layer, wherein thermal conductivity of the adhesive layer may be 0.5 W/m·K or more.
[11]According to an aspect of the present invention, there is provided an optical module in which the optical element assembly according to the above-described [1] to [10] is housed in a package.
[12]According to an aspect of the present invention, there is provided an optical engine including:
the optical module according to the above-described [11]; and
an optical scanning mirror configured to change an angle and reflect light output from the optical module so that an image is displayed.
[13] According to an aspect of the present invention, there are provided XR glasses equipped with the optical engine according to the above-described [12].
[14] According to an aspect of the present invention, there is provided a method for manufacturing an optical element assembly, the method including:
a bonding step of bonding a plurality of laser diode assemblies to an optical waveguide substrate via a plurality of metallic films,
wherein the optical waveguide substrate includes a substrate and an optical waveguide layer formed on a main surface of the substrate and having an optical waveguide,
wherein each laser diode assembly includes a base plate and a laser diode formed on the base plate, and
wherein the bonding step includes performing heating by applying laser light in a state in which at least one of the plurality of laser diode assemblies abuts against the substrate at a spacing from an adjacent laser diode assembly so that the mounting pitch satisfies formula (1).

$$P \geq W + 0.9 T \qquad ( 1 )$$

(P denotes a mounting pitch, W denotes a width of the base plate, and T denotes a thickness of the base plate)
[15] In the method for manufacturing the optical element assembly according to the above-described [14], the bonding step may include causing the base plate on which a first metallic film containing Au is formed to abut against the substrate on which a second metallic film containing Sn is formed, and performing heating to form a eutectic film of Au and Sn.
[16] In the method for manufacturing the optical element assembly according to the above-described [13] and [14], an Si substrate may be used as the base plate, and a YAG laser may be used in the bonding step.
[17] In the method for manufacturing the optical element assembly according to the above-described [1] to [16], the bonding step may include performing heating by applying laser light in a state in which at least one of the plurality of laser diode assemblies abuts against the substrate at a spacing from an adjacent laser diode assembly so that the mounting pitch satisfies formula (2) in the plurality of laser diode assemblies.

$$P \leq Wo - nW \qquad ( 2 )$$

(Wo denotes a width of the optical element assembly and n denotes the number of laser diode assemblies included in the optical element assembly)
[18] In the method for manufacturing the optical element assembly according to the above-described [13] to [17], the bonding step may include providing adjacent laser diode assemblies among the plurality of laser diode assemblies at spacings so that the mounting pitch satisfies formula (1).

According to the present invention, it is possible to provide an optical element assembly, a method for manufacturing the optical element assembly, an optical module, an optical engine, and XR glasses in which laser diode assemblies are mounted with high accuracy so that no thermal influence occurs on a base plate where other laser diodes are formed when a base plate on which the laser diode is formed is bonded to an optical waveguide substrate, and which offers a high degree of freedom in selecting a mounting position according to a shape of the laser diode assembly.

### BRIEF DESCRIPTION OF THE DRAWINGS

FIG. 1 is a perspective view showing an example of a configuration of an optical element assembly according to an embodiment of the present invention.

FIG. 2 is a plan view of the optical element assembly shown in FIG. 1.

FIG. 3A is a perspective view of a laser-light-source base plate on which three laser light sources are mounted.

FIG. 3B is a perspective view of an optical waveguide substrate having an optical waveguide.

FIG. 4 is a cross-sectional view taken along line A-A′ of the optical element assembly shown in FIG. 1.

FIG. 5 is a cross-sectional view taken along line B-B′ of the optical element assembly shown in FIG. 2.

FIG. 6A is a view schematically showing a structure in which both a first metallic film 74 and a second metallic film 72 remain to a certain extent.

FIG. 6B is a view schematically showing a structure in which the entirety of the first metallic film 74 and the second metallic film 72 is alloyed to form a eutectic layer.

FIG. 7 is an explanatory schematic view of a configuration of a method for manufacturing the optical element assembly according to an embodiment of the present invention and is a cross-sectional view showing a state of a bonding step.

FIG. 8 is an explanatory schematic diagram of a configuration of a method for manufacturing the optical element assembly according to an embodiment of the present invention and is a cross-sectional view showing a state of a bonding process.

FIG. 9 is a plan view showing an example of a configuration of an optical element assembly according to a modification example of FIG. 1 and is an enlarged view of a peripheral structure of a plurality of laser-diode assemblies.

FIG. 10 is a cross-sectional view showing an example of a configuration of an optical element assembly according to another modification example of FIG. 1.

FIG. 11 is a plan view showing an example of a configuration of an optical module according to an embodiment of the present invention.

FIG. 12 is a cross-sectional view of the optical module of FIG. 11.

FIG. 13 is an explanatory plan view of an internal configuration of a package in the optical module of FIG. 11.

FIG. 14 is a conceptual diagram showing XR glasses according to an embodiment of the present invention.

FIG. 15 is a conceptual diagram showing a state in which an image is directly projected onto a retina by laser light output from the optical module according to an embodiment of the present invention.

### DETAILED DESCRIPTION OF THE INVENTION

The present embodiments will be described in detail below with reference to the drawings as appropriate. In the drawings used in the following description, the characteristic parts may be enlarged for convenience to make it easier to understand the characteristics of the present disclosure in some cases and dimensional ratios of constituent elements may differ from the actual ones in some cases. The materials, the dimensions, and the like exemplified in the following description are examples and the present invention is not limited thereto. In addition, the embodiments can be implemented by appropriately modifying the materials, the dimensions, and the like exemplified in the following description within the range in which the effects of the present invention are exhibited.

### Optical Element Assembly

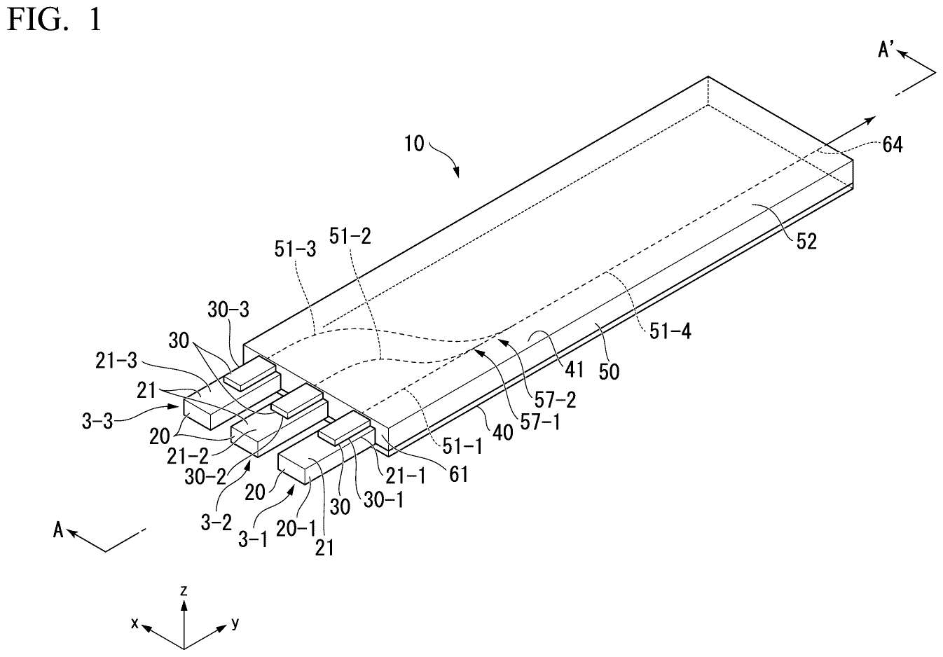

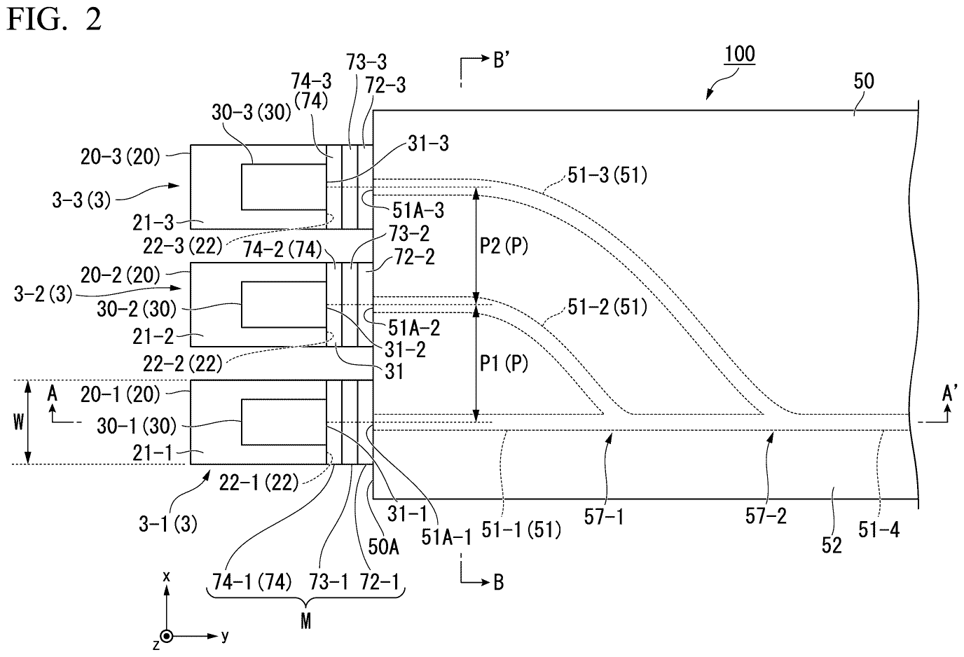

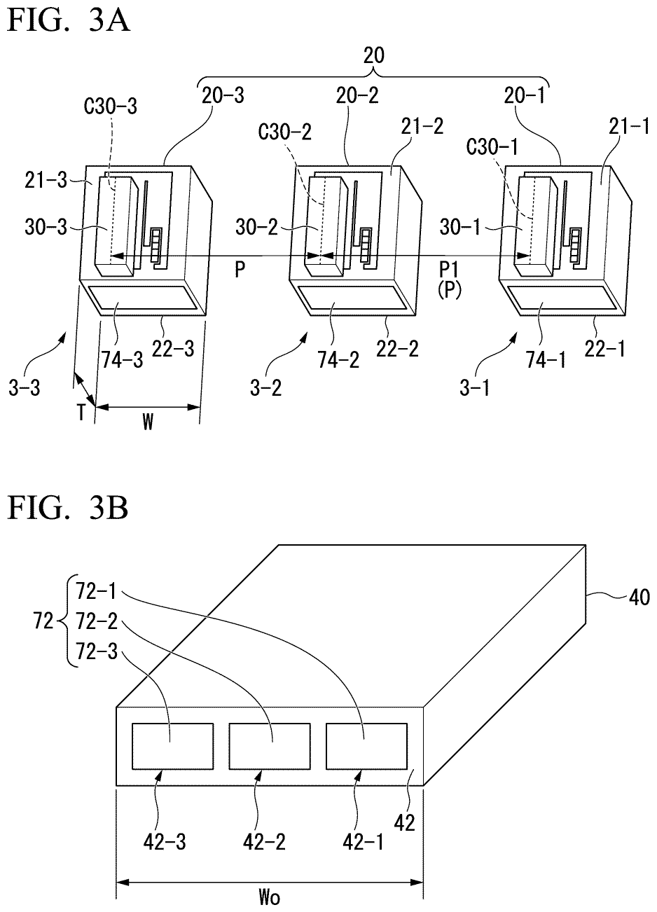

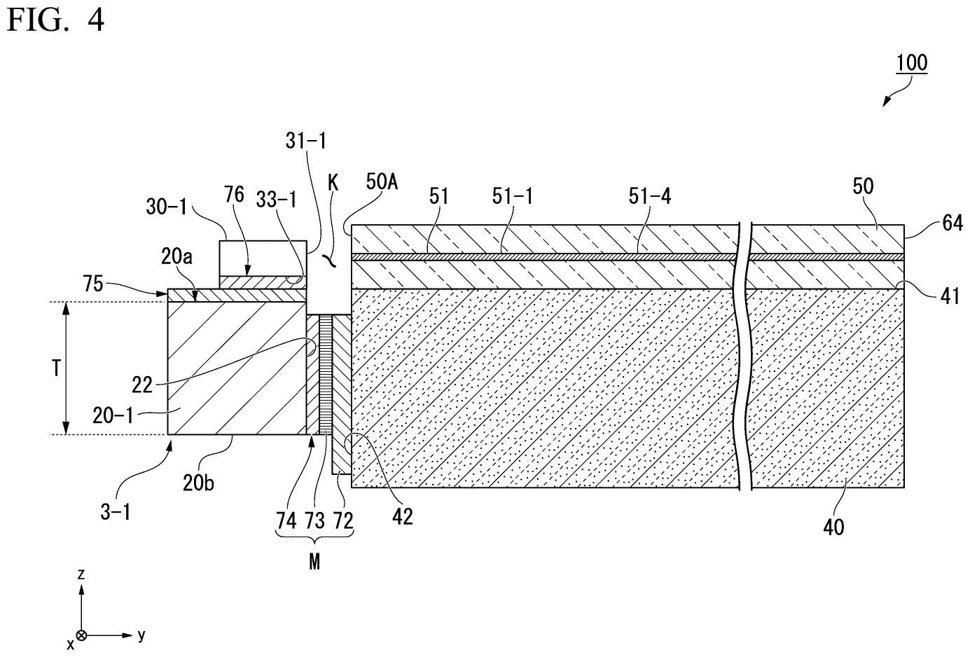

FIG. 1 is a perspective view showing an example of a configuration of an optical element assembly according to an embodiment of the present invention. FIG. 2 is a plan view of the optical element assembly shown in FIG. 1. FIG. 3A is a perspective view of a laser-light-source base plate on which three laser light sources are mounted. FIG. 3B is a perspective view of an optical waveguide substrate having an optical waveguide. FIG. 4 is a cross-sectional view taken along line A-A′ of the optical element assembly shown in FIG. 1.

The optical element assembly 100 shown in FIGS. 1 to 4 includes a plurality of laser diode assemblies 3 (3-1, 3-2, and 3-3) and an optical waveguide substrate 40 having a main surface on which an optical waveguide layer 50 having optical waveguides 51 that guide laser light output from the plurality of laser diode assemblies 3 is provided. The laser diode assembly 3 includes base plates 20 (20-1, 20-2, and 20-3) and laser diodes 30 (30-1, 30-2, 30-3) formed on the base plates 20, and at least one of the plurality of laser diode assemblies 3 is formed at a spacing from an adjacent laser diode assembly 3 so that the mounting pitch satisfies formula (1).

$$P \geq W + 0.9 T \qquad ( 1 )$$

(P denotes a mounting pitch, W denotes a width of the base plate, and T denotes a thickness of the base plate)

Although members will be described using reference signs O-1, O-2, and O-3 to distinguish them from one another when a member denoted by reference sign O is exemplified as having a feature different from that of any one of members denoted by reference signs O-1, O-2, and O-3 in the present embodiment, members having features common to all members will be described collectively with only reference sign O. Moreover, in the present embodiment, the base plate 20 is referred to as a laser-light-source base plate or a subcarrier. Moreover, the laser diode 30 is referred to as a laser light source.

As shown in FIG. 1, the optical element assembly 100 includes: three laser diodes 30; three laser-light-source base plates 20 (20-1, 20-2, and 20-3) having main surfaces 21-1, 21-2, and 21-3 on which three laser diodes 30 are placed and arranged to be spaced apart from one another; an optical waveguide layer 50 having at least optical waveguides 51 that guide laser light output from the three laser diodes 30 (30-1, 30-2, and 30-3); an optical waveguide substrate 40 having a main surface on which the optical waveguide layer 50 is provided; and a metallic film M configured to bond the laser-light-source base plates 20 (20-1, 20-2, and 20-3) and the optical waveguide substrate 40. The metallic film M (72, 73, and 74) is arranged between base-plate-side bonding surfaces 22 (22-1, 22-2, and 22-3) of the laser-light-source base plates 20 (20-1, 20-2, and 20-3) and a plurality of substrate-side bonding portions 42-1, 42-2, and 42-3 arranged to be spaced apart from one another in correspondence with the base-plate-side bonding surfaces 22 (22-1, 22-2, and 22-3) on the bonding surface 42 of the optical waveguide substrate 40, thereby bonding the laser-light-source base plates 20-1, 20-2, 20-3 to the optical waveguide substrate 40. Thus, in the optical element assembly 100, the plurality of laser diode assemblies 3 are bonded to the optical waveguide substrate 40 via the metallic film M including a plurality of metallic films.

### Laser Diodes and Base Plates for Laser Diodes

Various types of laser elements can be used as the laser diode 30. For example, commercially available laser diodes (LDs) for red light, green light, blue light, near-infrared light, ultraviolet light, and the like can be used. Light having a peak wavelength of 600 nm to 780 nm can be used as the red light; light having a peak wavelength of 500 nm to 560 nm can be used as the green light; and light having a peak wavelength of 430 nm to 500 nm can be used as the blue light. Moreover, light having a peak wavelength of 830 nm to 2000 nm can be used as the near-infrared light.

In the optical element assembly 100 shown in FIG. 1, it is assumed that the laser diodes 30-1, 30-2, and 30-3 are an LD that emits the red light, an LD that emits the green light, and an LD that emits the blue light, respectively. The LDs 30-1, 30-2, and 30-3 may each be implemented, for example, as a bare chip (an unpackaged chip) that can be mounted on individual laser-light-source base plates (subcarriers; hereinafter sometimes referred to simply as “subcarriers”) 20-1, 20-2, and 20-3.

The subcarriers 20-1, 20-2, and 20-3 are formed of, for example, aluminum nitride (AlN), silicon (Si), or the like.

Between the subcarrier 20 and the LD 30, a first metallic layer 75 and a second metallic layer 76 are provided (see FIG. 4). The subcarrier 20 and the LD 30 are connected via the first metallic layer 75 and the second metallic layer 76. Methods for forming the first metallic layer 75 and the second metallic layer 76 are not limited and any known method such as sputtering, vapor deposition, or coating of metal paste can be used. The first metallic layer 75 and the second metallic layer 76 may include, for example, one or more metals selected from the group consisting of gold (Au), platinum (Pt), silver (Ag), lead (Pb), indium (In), nickel (Ni), titanium (Ti), tantalum (Ta), tungsten (W), gold (Au)-tin (Sn) alloy, tin (Sn)-silver (Ag)-copper (Cu) solder alloy (SAC), SnCu, InBi, SnPdAg, SnBiIn, and PbBiIn, and may be formed of one or more metals selected from this group.

As shown in FIGS. 2 and 4, the base plate 20 has a width W corresponding to the length in the x-direction, and a thickness T corresponding to the length in the z-direction. The length of the base plate 20 in the y-direction may be referred to as a depth.

In FIG. 3A, an enlarged configuration of the LD 30 formed on the base plate 20 is shown. As shown in FIG. 3A, the LD 30 is formed on the base plate 20 along with an active layer corresponding to an output portion and electrode portions such as a cathode and an anode electrically connected to the active layer. The mounting pitch P in the above-described formula (1) is a spacing between adjacent laser diode assemblies 3 among the plurality of laser diode assemblies 3 and corresponds to a spacing between lasers applied from the LDs 30. That is, in each of the LDs 30-1, 30-2, and 30-3 in FIG. 3A, in the laser diode assembly 3 in which laser light is output in parallel to the widthwise centers C30-1, C30-2, and C30-3 from the widthwise centers C30-1, C30-2, and C30-3 of the output portions, the mounting pitch P is a distance between the widthwise centers C30-1 and C30-2 of the output portions and a distance between the widthwise centers C30-2 and C30-3. In FIG. 3A, the width W of the base plate 20 and the thickness T of the base plate 20 are shown. Moreover, in FIG. 3B, the width Wo of the optical waveguide layer 50 is shown. The width of the optical waveguide layer 50 is, for example, the same as the width of the substrate 40. Although the substrate-side bonding portions 42-1, 42-2, and 42-3 and the second metallic films 72-1, 72-2, and 72-3 provided in those regions are shown in FIG. 3B, the positions and spacings thereof can be adjusted in accordance with the positions and spacings at which the subcarriers 20-1, 20-2, and 20-3 are provided. The substrate-side bonding portions 42-1, 42-2, and 42-3 are provided to face the first metallic films 74-1, 74-2, and 74-3 provided on the subcarriers 20-1, 20-2, and 20-3.

In the optical element assembly 100 shown in FIGS. 1 to 4, the plurality of laser diode assemblies 3 are all provided with spacings between adjacent laser diode assemblies so that the mounting pitch satisfies formula (1). In the optical element assembly 100 shown in FIGS. 1 to 4, the thickness T and the width W of each of the base plates of the plurality of laser diode assemblies 3 are uniform, and the adjacent laser diode assemblies 3 are provided to be arranged at equal intervals.

As an example, one having a width W of 0.37 mm, a thickness T of 0.40 mm, and a depth of 0.40 mm can be used as the base plate 20 and one having a width of 2.25 mm, a height of 3.42 mm, and a depth of 0.415 mm can be used as the optical waveguide layer 50. When such a base plate 20 is used, W+0.9T=0.37+0.90×0.40=0.73 (mm). Accordingly, in accordance with formula (1), the mounting pitch P can be set to a size greater than 0.73 mm, and can be set to, for example, 0.75 mm. In this case, a relationship that the mounting pitch P is W+0.9T+0.02 (mm) is satisfied. For example, the mounting pitch P between adjacent laser diode assemblies 3 among the three laser diode assemblies 3 may be set to the above-described value and the assemblies may be mounted at equal intervals.

In the optical element assembly 100, the plurality of laser diode assemblies 3 are preferably provided to be spaced apart from adjacent laser diode modules so that the mounting pitch satisfies the following formula (2) from the standpoint of the securement of sufficient positional accuracy and compactness.

$$P \leq Wo - nW \qquad ( 2 )$$

(Wo denotes a width of the optical element assembly and n denotes the number of laser diode assemblies included in the optical element assembly)

### Optical Waveguide Layer and Optical Waveguide Substrate

The optical waveguide layer 50 includes at least an optical waveguide that guides laser light output from the laser light source. The optical waveguide layer is not particularly limited, and, for example, a known configuration may be adopted. Examples of the optical waveguide layer will be described below.

The optical waveguide layer 50 is referred to as a planar lightwave circuit (PLC). Hereinafter, the optical waveguide layer 50 may be referred to as a PLC 50. The optical waveguides 51-1, 51-2, and 51-3 may be referred to as cores 51-1, 51-2, and 51-3.

The optical waveguide layer 50 is formed on the optical waveguide substrate 40, and the laser light source 30 is placed on the subcarrier 20 placed as described above. The optical waveguide substrate 40 and the subcarrier 20 are integrated by metal bonding. According to this metal bonding, accurate optical-axis alignment becomes possible, and miniaturization is achieved.

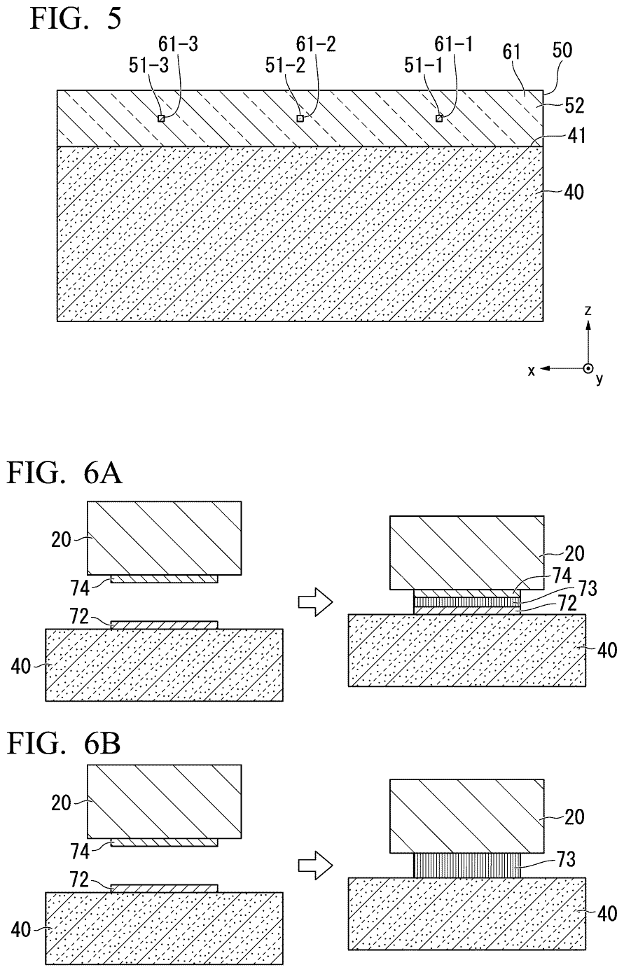

In FIG. 5, a schematic cross-sectional view of the optical element assembly 100 shown in FIG. 2 taken along line B-B′ is shown. The optical waveguide substrate 40 is made, for example, of silicon (Si). The PLC 50 is manufactured to be integrated with an optical waveguide substrate 40 on a top surface 41 by a semiconductor process including known photolithography and dry etching used in forming a fine structure such as an integrated circuit. As shown in FIG. 2, the cores 51-1, 51-2, and 51-3, which are equal in number to the LDs 30-1, 30-2, and 30-3, and a cladding 52 surrounding the cores 51-1, 51-2, and 51-3 are provided in the PLC 50. The thickness of the cladding 52 and the widthwise dimensions of the cores 51-1, 51-2, and 51-3 are not particularly limited. For example, the cores 51-1, 51-2, and 51-3 having widthwise dimensions on the order of several micrometers may be arranged within the cladding 52 having a thickness of about 50 μm.

The cores 51-1, 51-2, 51-3 and the cladding 52 are made, for example, of quartz. Hereinafter, they may be referred to as a quartz-based PLC 50. Refractive indices of the cores 51-1, 51-2, and 51-3 are higher than the refractive index of the cladding 52 by a predetermined value. Accordingly, light input to each of the cores 51-1, 51-2, and 51-3 propagates through each core while undergoing total internal reflection at an interface between each core and the cladding 52. In the cores 51-1, 51-2, and 51-3, for example, an impurity such as germanium (Ge) is doped by an amount according to the above-described predetermined value.

As shown in FIGS. 1, 2, and 4, the cores 51-1, 51-2, and 51-3 are gathered together into a single path just before reaching an output surface 64 of the PLC 50. That is, the cores 51-1, 51-2, and 51-3 sequentially merge in the forward direction along the x-direction and merge into a single core 51-4. Each of the cores 51-1, 51-2, and 51-3 is preferably connected to the core 51-4 at a curvature radius equal to or greater than a predetermined curvature radius so that no leakage of light from the cores 51-1, 51-2, and 51-3 occurs.

By metal bonding between the optical waveguide substrate 40 and the subcarrier 20, each core and the corresponding LD are arranged opposite each other with the optical axis accurately aligned so that the center of the input port of each of the cores 51-1, 51-2, 51-3 of the PLC 50 approximately coincides with the optical axis of the output light from each of the corresponding LDs 30-1, 30-2, and 30-3.

As shown in FIG. 4, the input surface 50A of the PLC 50 is arranged to face the output surface 31 of the LD 30. Specifically, the output surface 31-1 of the LD 30-1 faces an input port 51A-1 of the optical waveguide 51-1. In the x-and z-directions, the optical axis of the red light emitted from the LD 30-1 approximately overlaps the center of the input port 51A-1. Likewise, the output surface 31-2 of the LD 30-2 faces an input port 51A-2 of the optical waveguide 51-2. In the x-and z-directions, the optical axis of the green light emitted from the LD 30-2 approximately overlaps the center of the input port 51A-2. The output surface 31-3 of the LD 30-3 faces an input port 51A-3 of the optical waveguide 51-3. In the x-and z-directions, the optical axis of the blue light emitted from the LD 30-3 approximately overlaps the center of the input port 51A-3. With such a configuration and arrangement, at least some of the red, green, and blue light emitted from the LDs 30-1, 60-2, and 60-3 can be input to the optical waveguides 51-1, 51-2, and 51-3.

As shown in FIG. 2, the red light, the green light, and the blue light emitted from the LDs 30-1, 30-2, and 30-3 are input to the cores 51-1, 51-2, and 51-3 and then propagate through the cores. The red and green light propagating through the cores 51-3 and 51-2 are multiplexed at a predetermined merging position 57-1 located rearward in the y-direction from the merging position 57-2. The multiplexed red and green light and the blue light propagating through the core 51-2 are combined at the merging position 57-2. RGB light multiplexed at the merging position 57-2 propagates through the core 51-4, reaches the output surface 64, and is output from the output surface 64.

### Bonding Portion

The three individual laser-light-source base plates 20-1, 20-2, and 20-3 and the optical waveguide substrate 40 are bonded via the metallic film M.

The metallic film M is disposed between each of the base-plate-side bonding surfaces 22-1, 22-2, and 22-3 of the three individual laser-light-source base plates 20-1, 20-2, and 20-3, and the three substrate-side bonding portions 42-1, 42-2, and 42-3 corresponding to the base-plate-side bonding surfaces 22-1, 22-2, and 22-3 and arranged to be spaced apart from one another on the bonding surface 42 of the optical waveguide substrate 40.

Because the metallic film M is arranged only on the substrate-side bonding portions 42-1, 42-2, and 42-3 arranged apart from one another, and is a separated film instead of a continuously formed film, the occurrence of capacitive coupling is suppressed, and crosstalk is prevented.

For convenience, the metallic film M shown in FIGS. 2 and 4 is illustrated as having a three-layer structure that reflects a fabrication process of the metallic film M (or a bonding process on the laser-light-source base plate and the optical waveguide substrate). Moreover, in the description of the metallic film M, each of the three layers may be described.

That is, the metallic film M shown in the drawings is, for convenience, illustrated as having three layers: a first metallic film 74 (74-1, 74-2, and 74-3) arranged on the base-plate-side bonding surfaces 22-1, 22-2, and 22-3 of the individual laser-light-source base plates 20-1, 20-2, and 20-3; a second metallic film 72 (72-1, 72-2, and 72-3) arranged on three base-plate-side bonding portions 42-1, 42-2, and 42-3 corresponding to the base-plate-side bonding surfaces 22-1, 22-2, and 22-3 and arranged to be spaced apart from one another on the bonding surface 42 of the optical waveguide substrate 40; and a eutectic layer 73 arranged between the first metallic film 74 and the second metallic film 72.

In the actual bonding, when the first metallic film and the second metallic film are sufficiently thin, an alloy layer (eutectic layer) is formed and the first and second metallic films do not remain. On the other hand, when either the first metallic film or the second metallic film is thick, only the front surface side of the thick metallic film may become eutectic, such that only a part of the laser-light-source base plate side or the optical waveguide substrate side remains, while the other metallic film may become entirely eutectic, but it is difficult to distinguish them as clear layers (or distinguish an interface).

Thus, in the actual bonding, the film structure of the metallic film M varies depending on the conditions of the fabrication process of the metallic film M, and the drawings conceptually depict characteristic aspects of the film structure. For example, a structure in which one or both of the first metallic film 74 and the second metallic film 72 remain to a certain extent, or a structure in which the entirety of the first metallic film 74 and the second metallic film 72 is alloyed to form a eutectic layer is provided. FIG. 6A is a diagram schematically showing the former structure in which both the first metallic film 74 and the second metallic film 72 remain to a certain extent, and FIG. 6B is a diagram schematically showing the latter structure in which the entirety of the first metallic film 74 and the second metallic film 72 is alloyed to form a eutectic layer.

The first metallic film 74 is formed, for example, over the entire bonding surface 22 of the base plate 20, or over the entire area excluding the ends thereof. In order to achieve bonding by forming a eutectic between the first metallic film 74 and the second metallic film 72 through heating of the first metallic film 74, it is necessary to heat so that the entirety of the first metallic film 74 and the second metallic film 72 sufficiently melts, and this needs to be taken into consideration when defining the mounting pitch P of the laser diode assembly 3.

The first metallic film 74 and the second metallic film 72 are aligned to overlap each other and heated if laser light is applied directly to the subcarrier 20 or through the subcarrier, and the first metallic film 74 and the second metallic film 72 are melted. In a state in which the first metallic film 74 and the second metallic film 72 abut against each other, heating by the laser light causes the components of the second metallic film 72 to be eutectic and diffused into the first metallic film 74.

The second metallic film 72 arranged on the substrate-side bonding portions 42-1, 42-2, and 42-3 is preferably made of Sn or an alloy containing Sn, such as Sn-Ag-Cu. Moreover, the first metallic film 74 arranged on the base-plate-side bonding surfaces 22-1, 22-2, and 22-3 is preferably a metal capable of forming a eutectic with Sn, and, for example, may be one selected from the group consisting of Au, Si, Al, Ni, Pb, Zn, and Pt, or may include an alloy thereof. The first metallic film 74 is preferably Au or Pt among the metals capable of forming a eutectic with Sn. These metals require particularly high-temperature processing when forming a eutectic with Sn by reflow in the bonding process. Therefore, they tend to easily affect a nearby member such as a metallic film of a laser diode assembly adjacent to the laser diode assembly 3 in a state of bonding with the optical waveguide substrate 40. However, in the present embodiment, laser diode assemblies 3 adjacent to a target of the bonding process are provided to be spaced apart at a mounting pitch P, thereby preventing the thermal effects on the laser diode assemblies 3 located in a near area and providing an optical element assembly with a highly precisely adjusted mounting position.

Furthermore, the three-layer structure of the metallic film M (72, 73, and 74) shown in FIG. 6 may be reversed. That is, a structure in which the second metallic film 72 may be arranged on the laser-light-source base plate 20 side, and the first metallic film 74 may be arranged on the optical waveguide substrate 40 side may be provided.

### Method of Manufacturing Optical Element Assembly

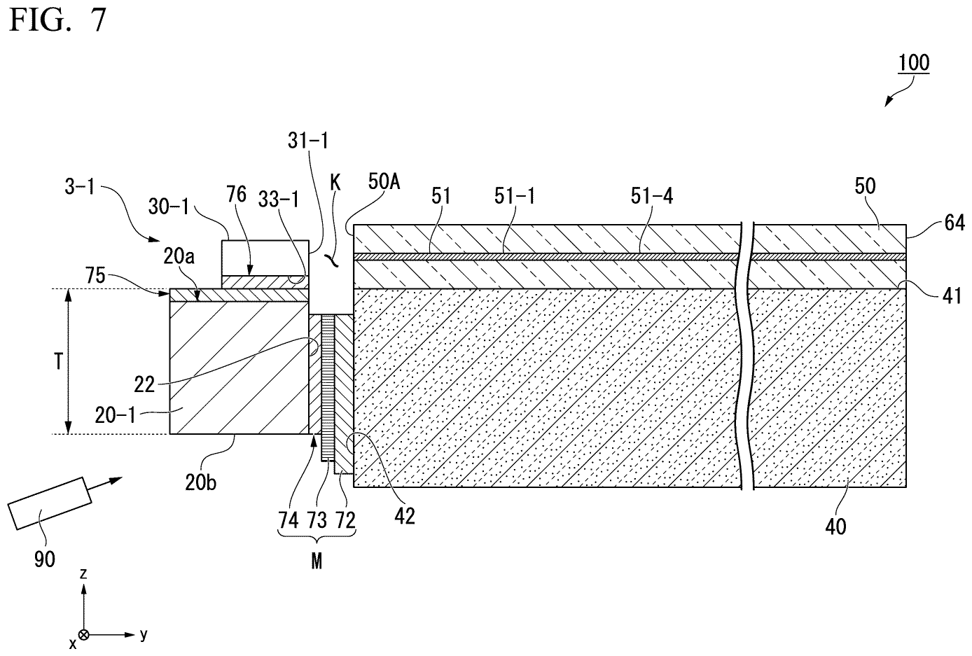

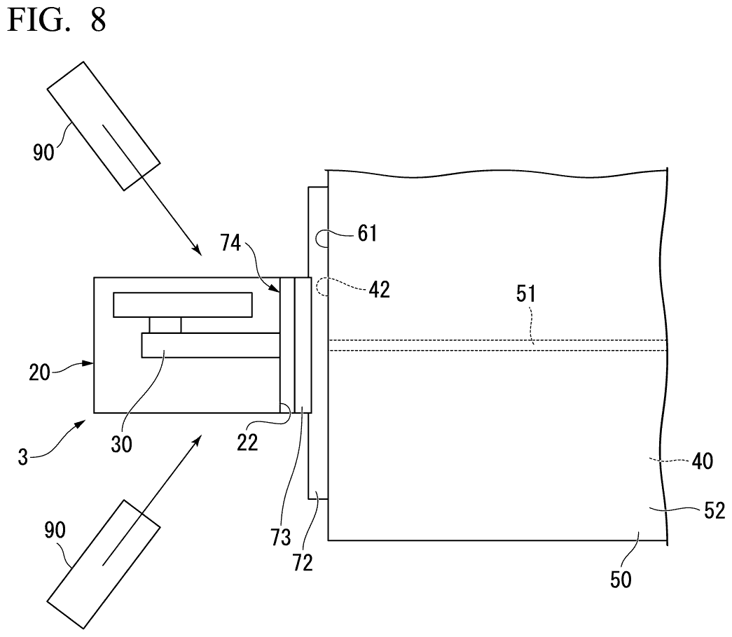

Hereinafter, a method for manufacturing an optical element assembly according to an embodiment of the present invention will be described as an example of the method for manufacturing the optical element assembly 100 according to the above-described embodiment. FIGS. 7 and 8 are explanatory schematic diagrams of the configuration of the method for manufacturing the optical element assembly according to an embodiment of the present invention, and are cross-sectional views showing a state of the bonding step.

The method for manufacturing the optical element assembly according to an embodiment of the present invention includes a bonding step of bonding a plurality of laser diode assemblies 3 to the optical waveguide substrate 40 via a plurality of metallic films 72 and 74. In the bonding step, laser light is applied for heating in a state in which at least one laser diode assembly among the plurality of laser diode assemblies 3 abuts against the substrate apart from an adjacent laser diode assembly 3 so that a mounting pitch satisfies formula (1).

$$P \geq W + 0.9 T \qquad ( 1 )$$

(P denotes a mounting pitch, W denotes a width of the base plate, and T denotes a thickness of the base plate)

The laser diode assembly 3 is formed by mounting a bare-chip LD 30 on the upper surface of the base plate 20 using a known method. For example, a first metallic layer 75 is formed on an upper surface 21 of the base plate 20 by sputtering or vapor deposition. Furthermore, a second metallic layer 76 is formed on a lower surface 33 of the LD 30 (e.g., the lower surface 33-1 of the LD 30-1) using sputtering, vapor deposition, or the like. Subsequently, laser light is applied to the base plate 20 so that only the base plate 20 is heated to a degree that it does not melt or deform. Heat is transferred from the base plate 20 to soften or melt the first metallic layer 75 and the second metallic layer 76 and cool the first metallic layer 75 and the second metallic layer 76. Thereby, the LD 30 is bonded to the upper surface 21 of the base plate 20 via the first metallic layer 75 and the second metallic layer 76, thereby forming the laser diode assembly 3.

Moreover, before or after the LD 30 is mounted onto the base plate 20, a first metallic film 74 is formed on the base-plate-side bonding surface 22 of the base plate 20. The first metallic film 74 may be formed using sputtering, vapor deposition, or the like.

Subsequently, the PLC 50 is formed on the top surface 41 of the substrate 40 by a known semiconductor process. Furthermore, the second metallic film 72 is formed on the substrate-side bonding portions 42-1, 42-2, and 42-3 of the substrate 40 by sputtering, vapor deposition, or the like.

Subsequently, the output surfaces 31 and the input surfaces 61 of the corresponding LDs 30 and the cores 51-1, 51-2, and 51-3 are arranged to face each other in the x-and z-directions with a gap in the y-direction. The optical axis of color light emitted from the LD 30 approximately overlaps the center of the corresponding input surface 61 of the core, and the base plate 20 on which the first metallic film 74 is formed and the substrate 40 on which the second metallic film 72 is formed abut against each other. Here, each laser diode assembly 3 in which the LD 30 is formed on the base plate 20 is bonded to the adjacent laser diode assembly 3 at a spacing so that a mounting pitch satisfies formula (1), as described below.

Specifically, as shown in FIGS. 7 and 8, laser light from the laser 90 is applied to the subcarrier 20, and heat transfer from the subcarrier 20 softens or melts the first metallic film 74, the second metallic film 72, and the third metallic film (eutectic film) 73. Relative positions of the LD 30 and the PLC 50 are adjusted, and the subcarrier 20 on which the LD 30 is mounted is bonded to the substrate 40 on which the PLC 50 is formed so that the bottom surface 23 of the subcarrier 20 and the bottom surface 43 of the substrate 40 are approximately on the same plane.

Although any known laser capable of heating the first metallic film 74 and the second metallic film 72 to a temperature at which eutectic bonding is achieved may be used as the laser 90, it is preferable to use a laser capable of applying laser light having a wavelength of 1064 nm or longer like a YAG laser. When laser light of a short wavelength is applied in the bonding process, the metallic film M is indirectly heated via the base plate 20. In the present embodiment, it is preferable to use the base plate 20 made of Si and use a laser such as a YAG laser having a wavelength of 1064 nm or longer in the bonding process. When the base plate 20 made of Si is used and a laser such as a YAG laser having a wavelength of 1064 nm or longer is used in the bonding process, the laser light applied from the laser 90 can be transmitted through the base plate 20 and can directly heat the metallic film M. Thus, an influence of thermal radiation on adjacent laser diode assemblies 3 from the base plate 20 can be further suppressed.

The method for manufacturing the optical element assembly according to the present embodiment is particularly effective when a metallic film containing Au is used as the first metallic film 74 and a metallic film containing Sn is used as the second metallic film 72. When Sn and Au in such a metallic film are made eutectic, the temperature becomes higher, and there is a concern that the temperature of the laser diode assembly 3 adjacent to the laser diode assembly 3 of a bonding target may easily become higher. However, according to the present embodiment, in the laser diode assemblies 3 of the bonding targets provided at a spacing so that a mounting pitch satisfies the above-described formula (1), the base plate 20 and the substrate 40 are bonded through the formation of an Au-Sn eutectic layer, such that it is possible to prevent the metallic film M of the adjacent laser diode assembly 3 from having a high temperature, and to manufacture an optical element assembly 100 that is aligned with high accuracy.

### Modification Example

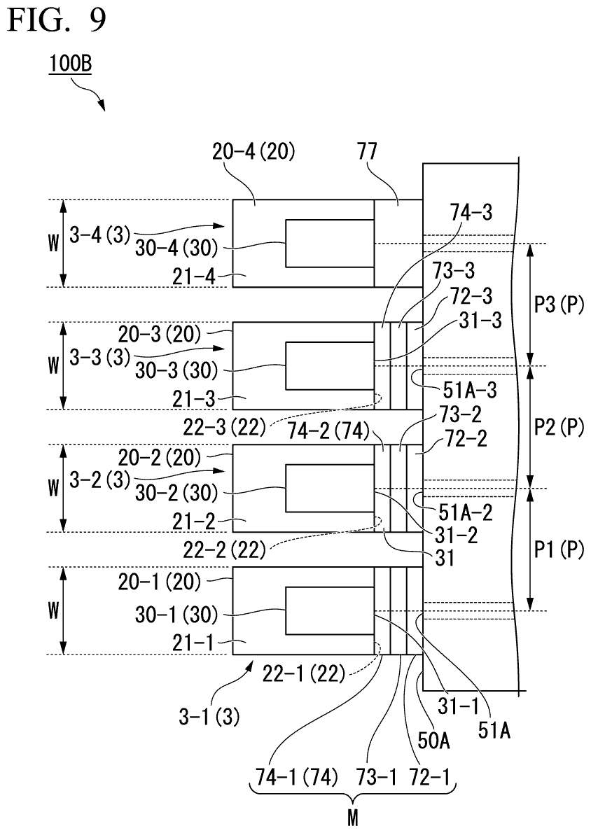

An optical element assembly according to an embodiment of the present invention is not limited to the configuration of the above-described embodiment, and various modifications are possible. For example, the optical element assembly according to the embodiment of the present invention can have a configuration as described below. FIG. 9 is a plan view showing an example of a configuration of an optical element assembly according to a modification example of FIG. 1, and is an enlarged view showing peripheral structures of a plurality of laser diode assemblies. In an optical element assembly 100B shown in FIG. 9, constituent elements similar to those of the optical element assembly according to the above-described embodiment are denoted by similar reference signs and descriptions thereof are omitted.

The optical element assembly 100B shown in FIG. 9 includes a laser diode assembly 3-4 in addition to the laser diode assemblies 3-1, 3-2, and 3-3. In the laser diode assembly 3-4, as in the other laser diode assemblies 3, the LD 30 is provided on the base plate 20 via, for example, the first metallic layer 75 and the second metallic layer 76. The base plate and the LD provided in the laser diode assembly 3-4 are referred to as a base plate 20-4 and an LD 30-4, respectively. The laser diode assembly 3-4 is bonded to the optical waveguide substrate 40 via, for example, an adhesive layer 77. The adhesive layer 77 is formed, for example, of an adhesive.

In the optical element assembly 100B, in consideration of the distance between the laser diode assemblies as will be described below, the laser diode assembly bonded to the optical waveguide substrate via a metallic film may be referred to as a first laser diode assembly, and the laser diode assembly adhered to the optical waveguide substrate 40 via an adhesive layer may be referred to as a second laser diode assembly. The optical element assembly 100B of the present modification example includes at least two first laser diode assemblies and at least one second laser diode assembly. The laser diode assemblies 3-1, 3-2, and 3-3 correspond to the first laser diode assemblies, and the laser diode assembly 3-4 corresponds to the second laser diode assembly.

In the optical element assembly 100B, the first laser diode assembly is provided at a spacing from an adjacent laser diode assembly 3 so that the mounting pitch satisfies formula (1). In the optical element assembly 100B, the plurality of laser diode assemblies 3-1, 3-2, 3-3, and 3-4 are arranged at unequal pitches. That is, among the adjacent laser diode assemblies, at least one laser diode assembly 3 is arranged at a distance from an adjacent laser diode assembly 3 different from a distance between other adjacent laser diode assemblies 3. In the optical element assembly 100B, the adjacent first laser diode assemblies, i.e., the first laser diode assemblies adjacent to each other, are provided at a spacing from each other so that a mounting pitch satisfies formula (1). A distance P1 between the laser diode assemblies 3-1 and 3-2, and a distance P2 between the laser diode assemblies 3-2 and 3-3 have, for example, the same length, and the laser diode assemblies 3-1, 3-2, and 3-3 are equally spaced. On the other hand, a distance P3 between the first laser diode assembly and the second laser diode assembly adjacent to each other, i.e., the distance between the laser diode assemblies 3-3 and 3-4 adjacent to each other, does not satisfy formula (1) and is, for example, shorter than the above distances P1 and P2. Furthermore, the distance P3 may be greater than or equal to the distances P1 and P2.

The first laser diode assembly is bonded to the optical waveguide substrate by the metallic film M, and is formed by a method similar to the bonding step in the method for manufacturing the optical element assembly according to the above-described embodiment. Therefore, from the viewpoint of suppressing a positional deviation of laser diode assemblies that are not the bonding target during the bonding step, the distance between these laser diode assemblies is preferably formed to satisfy the mounting pitch P. On the other hand, because the second laser diode assembly is adhered to the optical waveguide substrate 40 via the adhesive layer 77, its influence during bonding of an adjacent first laser diode assembly to the optical waveguide substrate 40 is minimal, and vice versa. Accordingly, in the optical element assembly 100B, the positions of the laser diode assemblies 3-1, 3-2, and 3-3 can also be aligned with high accuracy, and there is only a slight possibility that the positional deviation will occur in the laser diode assembly 3-4 when the laser diode assembly 3-3 is bonded and all laser diode assemblies 3 can be mounted on the optical waveguide substrate 40 with high accuracy.

Although an example of a configuration in which the dimensions of all base plates 20 are identical in the optical element assembly according to the above-described embodiment has been described, at least one base plate may have dimensions different from those of the other base plates. In the case of this configuration, in formulas (1) and (2), larger values are adopted as a width W and a thickness T among dimensions of the base plate 20 of the adjacent laser diode assembly 3. In the present embodiment, the optical element assembly does not fix the distance between the laser diode assemblies 3 to a specific value and has a configuration with a high degree of freedom by designing the spacing according to the dimensions of the laser diode assemblies 3.

Moreover, according to the optical element assembly of the above embodiment, by providing a plurality of independent laser diode assemblies 3, it is possible to separate the electrical influences between the laser diode assemblies 3 and to mutually eliminate the influences of heat and the like, and it is also possible to strictly manage the precision of each part and eliminate the electrical, thermal, and optical influences that occur, for example, when a plurality of laser diodes are mounted on a single subcarrier and further attached to the substrate 40. Here, when separate and independent laser diode assemblies such as those of the present embodiment are attached to the substrate 40, various types of dimensions are affected by a reflow method that depends on the process or bonding method. The optical element assembly according to the present embodiment prescribes the dimensions of the subcarrier and the pitch of the waveguides in consideration of these factors.

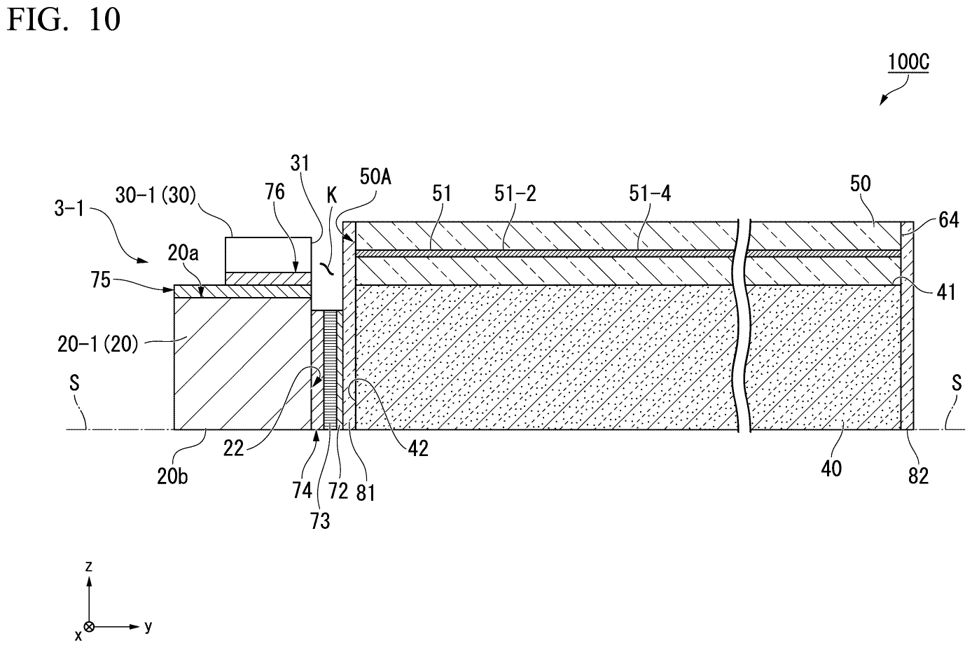

Moreover, FIG. 10 is a cross-sectional view showing an example of the configuration of an optical element assembly according to another modification example of FIG. 1. In an optical element assembly 100C shown in FIG. 10, an anti-reflection film 81 is provided between the LD 30 and the PLC 50. For example, the anti-reflection film 81 is integrally formed on the bonding surface 42 of the substrate 40 and the input surface 50A of the PLC 50. However, the anti-reflection film 81 may be formed only on the input surface 50A of the PLC 50.

In the optical element assembly 100C shown in FIG. 10, in addition to the input surface 50A, an anti-reflection film 82 is also provided on the output surface 64.

The anti-reflection films 81 and 82 are films that prevent light input to or output from the PLC 50 from being reflected in a direction opposite to the direction in which the light enters each surface from the input surface 50A or the output surface 64, and that increase the transmittance of the input or output light. The anti-reflection films 81 and 82 are multilayer films formed, for example, by alternately laminating a plurality of types of dielectric materials with predetermined thicknesses corresponding to the wavelengths of red, green, and blue light that is the input light. Examples of such dielectric materials include titanium oxide (TiO₂), tantalum oxide (Ta₂O₅), silicon oxide (SiO₂), aluminum oxide (Al₂O₃), and the like.

The output surface 31 of the LD 30 and the input surface 50A of the PLC 50 are arranged at a predetermined spacing. The input surface 50A faces the output surface 31, and a gap K is present between the output surface 31 and the input surface 50A in the x-direction. In view of the fact that the optical element assembly 100C is used for XR glasses, a required amount of light for XR glasses, and the like, the size of the gap (distance) K in the x-direction is, for example, greater than 0 μm and less than or equal to 5 μm.

Although the optical element assembly 100C shown in FIG. 10 will be described below, the same is true for the optical element assembly 100.

In the optical element assembly 100C, a bottom surface (base plate bottom surface) 20b facing a top surface (front surface) 20a of the subcarrier (laser-light-source base plate) 20 (20-1, 20-2, and 20-3) and a bottom surface (substrate bottom surface) 43 facing the top surface (front surface) 41 of the substrate 40 are arranged to be positioned on approximately the same plane S. Because the subcarrier 20 and the substrate 40 are connected via a metallic film in the optical element assemblies 100 and 100C, a positional deviation caused by the bonding process is significantly suppressed compared with the case where they are connected by an adhesive.

In addition, the term “approximately the same plane S” herein allows a slight deviation between the bottom surface 20b and the bottom surface 43. Specifically, a deviation of a range of 20 μm or less is allowable relative to the thickness of the substrate 40 in the z-direction, but it is preferable that the deviation be as small as possible, more preferably 10 μm or less, and even more preferably 5 μm or less.

If the bottom surface 20b of the subcarrier 20 and the bottom surface 43 of the substrate 40 are formed to be on approximately the same plane S as in the optical element assembly 100C shown in the drawing, both the subcarrier 20 and the substrate 40 can be bonded, for example, to a single plane of a package or a heat sink. Thereby, compared with when the bottom surface of the subcarrier and the bottom surface of the substrate are not on approximately the same plane and only one bottom surface thereof can be bonded, the optical element assembly 100C can efficiently dissipate heat generated during an operation of the LD (optical semiconductor element) 30 from both the bottom surface 20b of the subcarrier 20 and the bottom surface 43 of the substrate 40.

Moreover, as in the optical element assembly 100C shown in the drawing, by providing the bottom surface 20b of the subcarrier 20 and the bottom surface 43 of the optical waveguide substrate 40 on approximately the same plane S, when the optical module is bonded to one plane of another substrate or the like, both the bottom surface 20b of the subcarrier 20 and the bottom surface 43 of the optical waveguide substrate 40 can be bonded to one plane of the substrate or the like, such that the bonding strength can be maintained high and an optical element assembly 100C with excellent impact resistance can be implemented.

For example, when the bottom surface of the subcarrier is positioned above the bottom surface of the substrate in the +z-direction, i.e., when the bottom surface of the subcarrier is arranged further upward and away from the base 180 of a package 110 than the bottom surface of the substrate (see FIG. 12), a size of the first side surface of the subcarrier becomes small, heat dissipation cannot be performed efficiently, and the bonding strength with the substrate is insufficient, which may cause the subcarrier to slip off when wire bonding to be described below is performed. However, in the optical element assemblies 100 and 100C shown in the drawing, the size of the side surface of the base plate 20 is sufficiently ensured, and heat dissipation from both the bottom surface 20b and the side surface of the base plate 20 and bonding with the optical waveguide substrate 40 can be sufficiently performed, thereby improving heat dissipation performance and impact resistance. By improving impact resistance, for example, the LD 30 can be maintained at an optimal position relative to the PLC 50. Accordingly, the desired optical utilization efficiency and optical characteristics of the optical element assembly 100C can be achieved, and the reliability of the optical element assemblies 100 and 100C can be enhanced.

### Optical Module

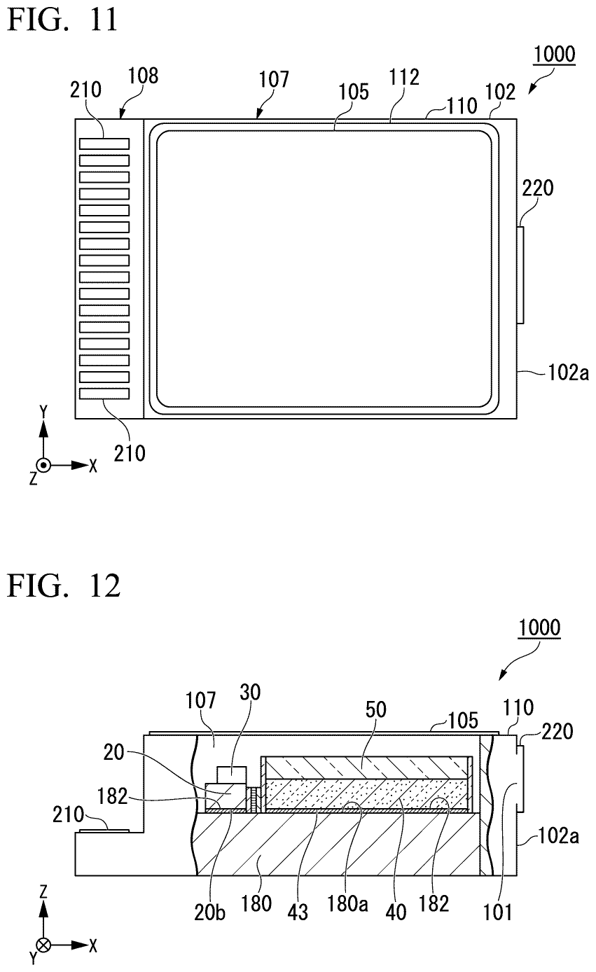

FIG. 11 is a schematic plan view of the optical module according to the present embodiment. FIG. 12 is a schematic cross-sectional view taken along an X-Z plane of the optical module shown in FIG. 11.

The optical module 1000 shown in FIG. 11 houses the optical element assembly according to the above-described embodiment inside the package 110. The optical element assembly shown in FIG. 11 is also referred to as a laser assembly.

The package 110 may include known constituent elements in addition to the optical element assembly according to the above-described embodiment. For example, a photodetector (PD) may be housed therein.

When the PD is provided, the light output variation of the LD can be checked by observing an electric current flowing through the PD. Moreover, a drive current for the LD can be controlled so that an output is uniform by monitoring an electric current flowing through the PD.

The package 110 includes a main body 102 having a cavity structure and a cover 105 that covers the main body 102.

The main body 102 has a bottom portion on which members housed inside are placed and a wall portion (sidewall portion) 102a arranged to surround those members laterally.

In the wall portion (sidewall portion) 102a arranged in a direction in which laser light is output, an optical transmission window 101 is formed so that the laser light L output from the laser light source 30 can be optically transmitted therethrough.

Among sidewall portions of the housing portion 107, an optical transmission window (opening) 101 is formed on the sidewall portion 102a near the output portion of the laser light L output from the optical module 1000. The opening 101 is formed approximately centered at a position intersecting the optical axis of the laser light output from the sidewall portion 102a. The opening 101 is covered from the outside of the sidewall portion 102a by a glass plate 220 without a gap. In other words, the housing portion 107 is hermetically sealed by the glass plate 220 in addition to the cover 105. Although the glass plate 220 is used for hermetic sealing, the material is not limited to the glass plate as long as it allows laser light to be transmitted therethrough. An anti-reflection film (not shown) may also be provided on both plate surfaces of the glass plate 220.

The electrode portion 108 is arranged on the near side in the x-direction, i.e., on the rear side in the x-direction, of the housing portion 107. A top surface of the electrode portion 108 is positioned below a top surface of the housing portion 107 and a bottom surface of the electrode portion 108 is positioned at approximately the same height as a bottom surface of the housing portion 107. On the top surface of the electrode portion 108, a plurality of external electrode pads 210 are provided at spacings in the y-direction.

As shown in FIG. 10, the base 180 for installing an optical module including the LD 30, the subcarrier 20 on which the LD 30 is placed, the PLC 50, and the optical waveguide substrate 40 on which the PLC 50 is formed is provided at a predetermined position on the bottom portion of the housing portion 107. This optical module is provided on the base 180. That is, the optical module is arranged in the internal space of the housing portion 107. Because this optical module is formed so that the bottom surface (base-plate bottom surface) 20b of the subcarrier (laser-light-source base plate) 20 and the bottom surface (substrate bottom surface) 43 of the optical waveguide substrate 40 are positioned on approximately the same plane S, the subcarrier 20 and the optical waveguide substrate 40 of the optical module are both bonded to an upper surface 180a (one inner surface) of the base 180.

It is only necessary for the bottom surface (base-plate bottom surface) 20b of the subcarrier 20 and the bottom surface (substrate bottom surface) 43 of the optical waveguide substrate 40 to be bonded to the upper surface 180a (one inner surface) of the base 180 via an adhesive layer 182. A material obtained by mixing a filler into a resin is used for the adhesive layer 182 to enhance thermal conductivity. Examples of the resin constituting the adhesive layer 182 include epoxy resin. Moreover, as fillers for improving the thermal conductivity of the resin, copper powder, aluminum powder, alumina powder, and the like can be used.

In addition, to maintain thermal conductivity of a certain level or higher, the adhesive layer 182 preferably has a thermal conductivity of 0.5 W/m·K or more, more preferably has a thermal conductivity of 1 W/m·K or more, and even more preferably has a thermal conductivity of 4 W/m·K or more.

As described above, by bonding both the subcarrier 20 of the optical module and the optical waveguide substrate 40 to the upper surface 180a of the base 180 of the package 110, heat generated by the operation of the LD 30 can be efficiently dissipated toward the base 180 from both the bottom surface (base-plate bottom surface) 20b of the subcarrier 20 and the bottom surface (substrate bottom surface) 43 of the optical waveguide substrate 40. Moreover, by bonding both the bottom surface 20b of the subcarrier 20 and the bottom surface 43 of the optical waveguide substrate 40 using an adhesive layer made of a resin mixed with filler, heat can efficiently propagate toward the base 180 from both the bottom surface 20b of the subcarrier 20 and the bottom surface 43 of the optical waveguide substrate 40.

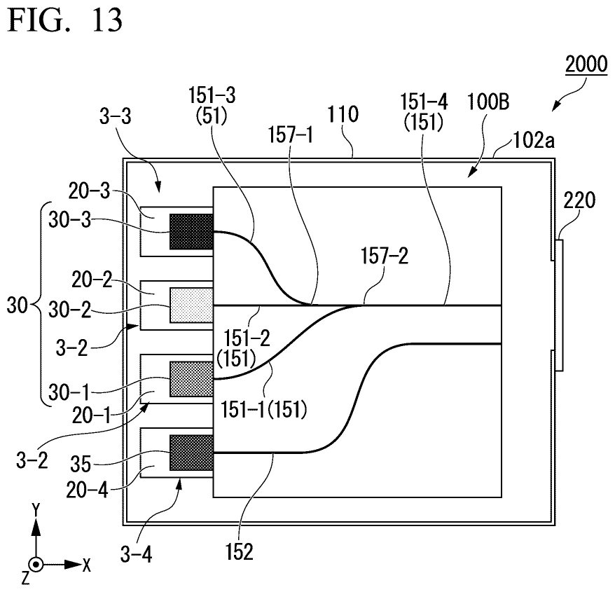

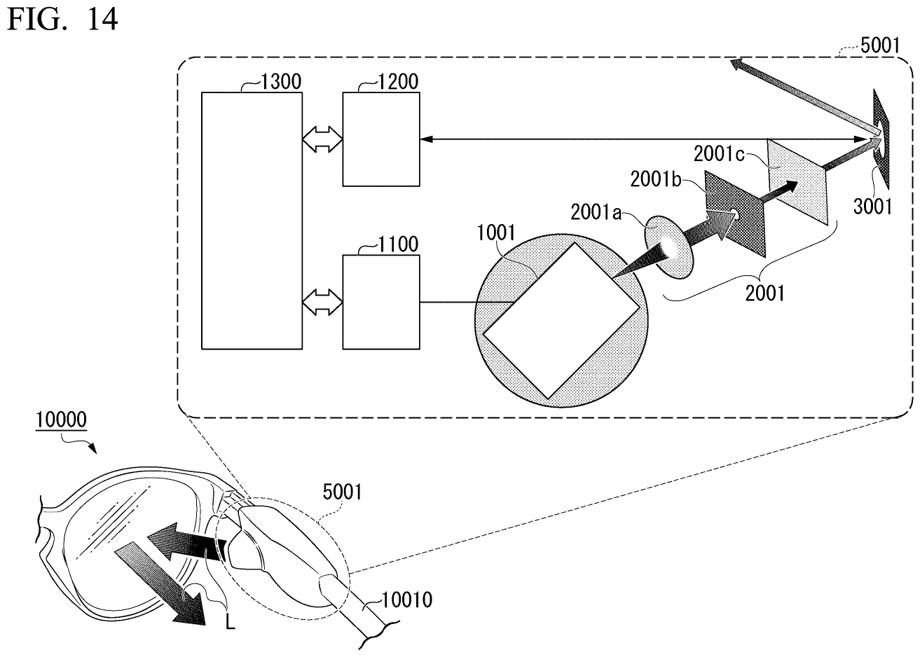

FIG. 13 is a conceptual diagram of an optical module including an optical waveguide layer having an optical waveguide, and shows an explanatory plan view of an internal configuration of the package in the optical module of FIG. 11.

Members identical to those of the above-described optical element assembly are designated by the same reference signs and detailed description thereof may be omitted. In FIG. 13, an example in which the optical element assembly further includes a near-infrared laser light source in addition to RGB laser light sources as the laser light sources is shown. Because near-infrared laser light is invisible, it can be used for eye-tracking.

In the optical module 2000 shown in FIG. 13, an optical element assembly 100B is housed in the package 110, and the optical element assembly 100B includes an RGB laser light source 30, a laser-light-source base plate 20 on which the RGB laser light source 30 is placed, a near-infrared laser light source 35, a laser-light-source base plate 20-4 on which the near-infrared laser light source 35 is placed, an optical waveguide substrate 140 having a main surface on which a PLC 150 is formed, and the metallic films 72, 73, and 74 that bond the laser-light-source base plate 20, the laser-light-source base plate 20-4, and the optical waveguide substrate 140.

The near-infrared laser light source 35 is mounted on the subcarrier 20-4 like the laser light source 30, and the PLC 150 is formed on the optical waveguide substrate 140.

The optical module 2000 includes the PLC 150 including the optical waveguides 151 (151-1, 151-2, 151-3) that guide laser light output from the laser light sources 30, and the optical waveguide 152 that guides near-infrared laser light output from the near-infrared laser light source 35 within the package 110.

Also, in the optical module 2000, the optical waveguide substrate 140 on which the PLC 150 is formed is metal-bonded to and integrated with the subcarrier 20 on which the laser light source 30 is placed and the subcarrier 20-4 on which the near-infrared laser light source 35 is placed.

This metal bonding enables accurate optical-axis alignment, and also achieves miniaturization.

Examples of the optical waveguide substrate 140 include a sapphire substrate, an Si substrate, a thermally oxidized silicon substrate, and the like.

As shown in FIG. 13, the optical waveguides 151-1, 151-2, and 151-3 are gathered together just before reaching the output surface of the PLC 150. That is, the optical waveguides 151-1, 151-2, and 151-3 merge in order as they move forward in the x-direction, and merge into one optical waveguide 151-4. To prevent leakage light from the optical waveguides 151-1, 151-2, and 151-3, the optical waveguides 151-1, 151-2, and 151-3 are preferably connected to the optical waveguide 151-4 with a curvature radius greater than or equal to a predetermined curvature radius.

By metal bonding between the optical waveguide substrate 140 and the subcarrier 20, each ridge and each corresponding LD are arranged facing each other in a state in which the optical axis is precisely aligned so that the center of the input port of each of the ridges 151-1, 151-2, 151-3, and 152 of the PLC 50 and the optical axis of the output light from each of the corresponding LD 30-1, 30-2, 30-3, and 35 approximately coincide with each other and optically connected to each other.

The input ports of the optical waveguides 151-1, 151-2, 151-3, and 152 face the output ports of the LDs 30-1, 30-2, 30-3, and 35 and are aligned so that light output from the output ports of the LDs 30-1, 30-2, 30-3, and 35 can be input to the corresponding input ports. Thus, the LDs 30-1, 30-2, 30-3, and 35 and the optical waveguides 151-1, 151-2, 151-3, and 152 are optically connected.

As shown in FIG. 13, the red light, green light, and blue light emitted from the LDs 30-1, 30-2, and 30-3 are input to the input ports of the optical waveguides (ridges) 151-1, 151-2, and 151-3 and then propagate through the respective ridges. The red light and the green light propagating through the ridges 151-3 and 151-2 are multiplexed at a predetermined merging position 157-1, which is behind the merging position 157-2 in the x-direction. The multiplexed red and green light and the blue light propagating through the ridge 151-2 are multiplexed at the merging position 157-2. The RGB light multiplexed at the merging position 157-2 propagates through the ridge 151-4, reaches the output surface, and is output from the output surface.

Moreover, the near-infrared light emitted from the LD 35 propagates through the ridge 152, reaches the output surface, and is output from the output surface.

Each of the optical waveguides 151-1, 151-2, 151-3, and 152 provided in the PLC 150 may be a Mach-Zehnder-type optical waveguide.

### XR Glasses

The XR glasses according to the present embodiment include the above-described optical module mounted on the glasses according to the present embodiment.

The XR glasses (eyewear) are a glasses-type terminal, and “XR” is a general term for virtual reality (VR), augmented reality (AR), and mixed reality (MR).

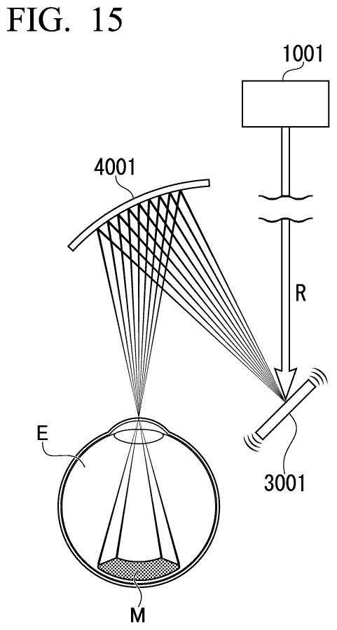

FIG. 15 is an explanatory conceptual diagram of the XR glasses according to the present embodiment.

The XR glasses 10000 shown in FIG. 15 have an optical module 1001 mounted on a frame 10010. Reference sign L denotes image display light.

In FIG. 15, the optical module 1001, an optical scanning mirror 3001, and an optical system 2001 connecting the optical module 1001 and the optical scanning mirror 3001 are collectively referred to as an optical engine 5001 in the present specification. Any of the optical modules according to the above-described embodiment may be used as the optical module 1001. The optical engine is also referred to as an optical engine module.

As the light sources in the optical module 1001, for example, a light source including RGB laser light sources of the red laser light source 30-1, the green laser light source 30-2, and the blue laser light source 30-3, and the near-infrared laser light source 35 can be used.

As the light sources in the optical module 1001, for example, a light source including RGB laser light sources of the red laser light source 30-1, the green laser light source 30-2, and the blue laser light source 30-3, and the near-infrared laser light source 35 may be used.

As shown in FIG. 16, laser light applied from the optical module 1001 mounted on the glasses frame is reflected by the optical scanning mirror 3001, and the reflected light is reflected by a mirror 4001 toward a human eyeball E direction, entering the human eyeball E and directly projecting an image (video) onto a retina M.

By providing an eye-tracking mechanism, eye-tracking can be performed while the image is directly projected onto the retina. A known mechanism can be used as the eye-tracking mechanism.

The optical scanning mirror 3001 is, for example, a MEMS mirror. To project a 2D image, the optical scanning mirror 3001 is preferably a two-axis MEMS mirror that oscillates to reflect the laser light while changing angles in the horizontal (X-direction) and vertical (Y-direction) directions.

The optical system 2001 that optically processes the laser light output from the optical module 1001 includes a collimator lens 2001a, a slit 2001b, and an ND filter 2001c. This optical system is an example and may have another configuration.

The optical engine 5001 includes a laser driver 1100, an optical scanning mirror driver 1200, and a video controller 1300 that controls these drivers.

Although the embodiments of the present invention have been described above in detail, the present invention is not limited to these embodiments. Various omissions, substitutions, and modifications may be made without departing from the spirit or scope of the invention as defined in the appended claims. Such embodiments and their modifications are also included within the scope and spirit of the invention, as well as within the equivalents thereof as set forth in the claims.

### EXPLANATION OF REFERENCES

3, 3-1, 3-2, 3-3, 3-4 Laser diode assembly
20, 20-1, 20-2, 20-3, 20-4 Base plate (laser-light-source base plate, subcarrier)
20a Top surface (front surface)
20b Bottom surface (base-plate bottom surface)
21 Upper surface
21-1, 21-2, 21-3 Main surface
22, 22-1, 22-2, 22-3 Base-side bonding surface
23 Bottom surface
30, 30-1, 30-2, 30-3 Laser diode (laser light source)
30-1 Red laser light source
30-2 Green laser light source
30-3 Blue laser light source
31, 31-1, 31-2, 31-3 Output surface
33, 33-1 Lower surface
35 Near-infrared laser light source
40 Optical waveguide substrate (substrate)
41 Top surface (front surface)
42 Bonding surface
42-1, 42-2, 42-3 Substrate-side bonding portion
43 Bottom surface (substrate bottom surface)
50 Optical waveguide layer
50A Input surface
51, 51-1, 51-2, 51-3 Optical waveguide (core)
51A-1, 51A-2, 51A-3 Input port
52 Cladding
57-1, 57-2 Merging position
61 Input surface
64 Output surface
72, 73, 74 Metallic film
72, 72-1, 72-2, 72-3 Second metallic film
73 Third metallic film (eutectic film)
74, 74-1, 74-2, 74-3 First metallic film
75 First metallic layer
76 Second metallic layer
77 Adhesive layer
81, 82 Anti-reflection coating
90 Laser
100, 100B, 100C Optical element assembly
101 Optical transmission window (opening)
102 Main body
102a Wall (side wall)
105 Cover
107 Housing
108 Electrode portion
110 Package
140 Optical waveguide substrate
151, 151-1, 151-2, 151-3 Optical waveguide (ridge)
157-1, 157-2 Merging position
180 Base
180a Upper surface
182 Adhesive layer
1000, 1001, 2000 Optical module
1100 Laser driver
1200 Optical scanning mirror driver
1300 Video controller
2001a Collimator lens
2001b Slit
2001c ND filter
3001 Optical scanning mirror
4001 Mirror
5001 Optical engine
10000 XR glasses
10010 Frame

What is claimed is:

1. An optical element assembly comprising:
a plurality of laser diode assemblies; and
an optical waveguide substrate having a main surface on which an optical waveguide layer having an optical waveguide for guiding laser light output from the plurality of laser diode assemblies is provided,
wherein each of the laser diode assemblies includes a base plate and a laser diode formed on the base plate, and
wherein at least one of the plurality of laser diode assemblies is provided at a spacing from an adjacent laser diode assembly so that a mounting pitch satisfies formula (1);
$$P \geq W + 0.9 T \qquad ( 1 )$$
(P denotes a mounting pitch, W denotes a width of the base plate, and T denotes a thickness of the base plate).

2. The optical element assembly according to claim 1, wherein the plurality of laser diode assemblies are provided at unequal pitches.

3. The optical element assembly according to claim 1, wherein the plurality of laser diode assemblies are provided at spacings so that adjacent laser diode assemblies have the mounting pitch satisfying formula (1).

4. The optical element assembly according to claim 3, wherein the plurality of laser diode assemblies are provided so that spacings between the adjacent laser diode assemblies are equal.

5. The optical element assembly according to claim 1, wherein the laser diode assemblies are bonded to the optical waveguide substrate via a plurality of metallic films, respectively.

6. The optical element assembly according to claim 5, wherein the plurality of metallic films include Sn and Au.

7. The optical element assembly according to claim 1, wherein the plurality of laser diode assemblies are formed so that a mounting pitch satisfies formula (2);
$$P \leq Wo - nW \qquad ( 2 )$$
(Wo denotes a width of the optical element assembly and n denotes the number of laser diode assemblies included in the optical element assembly).

8. The optical element assembly according to claim 2,
wherein the plurality of laser diode assemblies include at least two first laser diode assemblies adjacent to each other and bonded to the optical waveguide substrate via a plurality of metallic films and at least one second laser diode assembly adhered to the optical waveguide substrate via an adhesive layer,
wherein the adjacent first laser diode assemblies among the plurality of laser diode assemblies are provided at spacings P so that the mounting pitch satisfies formula (1), and
wherein a spacing between the second laser diode assembly and an adjacent laser diode assembly is less than the spacing P.

9. The optical element assembly according to claim 5, wherein the plurality of metallic films include a eutectic film of Sn and Au or a eutectic film of Sn and Pt.

10. The optical element assembly according to claim 1, further comprising a base in which the base plate and the optical waveguide substrate are bonded via an adhesive layer,
wherein thermal conductivity of the adhesive layer is 0.5 W/m·K or more.

11. An optical module in which the optical element assembly according to claim 1 is housed in a package.

12. An optical engine comprising:
the optical module according to claim 11; and
an optical scanning mirror configured to change an angle and reflect light output from the optical module so that an image is displayed.

13. XR glasses equipped with the optical engine according to claim 12.

14. A method for manufacturing an optical element assembly, the method comprising:
a bonding step of bonding a plurality of laser diode assemblies to an optical waveguide substrate via a plurality of metallic films,
wherein the optical waveguide substrate includes a substrate and an optical waveguide layer formed on a main surface of the substrate and having an optical waveguide,
wherein each laser diode assembly includes a base plate and a laser diode formed on the base plate, and
wherein the bonding step includes performing heating by applying laser light in a state in which at least one of the plurality of laser diode assemblies abuts against the substrate at a spacing from an adjacent laser diode assembly so that the mounting pitch satisfies formula (1);
$$P \geq W + 0.9 T \qquad ( 1 )$$
(P denotes a mounting pitch, W denotes a width of the base plate, and T denotes a thickness of the base plate).

15. The method for manufacturing the optical element assembly according to claim 14, wherein the bonding step includes causing the base plate on which a first metallic film containing Au is formed to abut against the substrate on which a second metallic film containing Sn is formed, and performing heating to form a eutectic film of Au and Sn.

16. The method for manufacturing the optical element assembly according to claim 14,
wherein an Si substrate is used as the base plate, and
wherein a YAG laser is used in the bonding step.

17. The method for manufacturing the optical element assembly according to claim 14, wherein the bonding step includes performing heating by applying laser light in a state in which at least one of the plurality of laser diode assemblies abuts against the substrate at a spacing from an adjacent laser diode assembly so that the mounting pitch satisfies formula (2) in the plurality of laser diode assemblies;
$$P \leq Wo - nW \qquad ( 2 )$$
(Wo denotes a width of the optical element assembly and n denotes the number of laser diode assemblies included in the optical element assembly).

18. The method for manufacturing the optical element assembly according to claim 14, wherein the bonding step includes providing adjacent laser diode assemblies among the plurality of laser diode assemblies at spacings so that the mounting pitch satisfies formula (1).
